(19) United States
(12) Patent Application Publication
(10) Pub. No.: US 2025/0285936 A1
(43) Pub. Date: Sep. 11, 2025

(54) SEMICONDUCTOR APPARATUS AND HEAT SINK

(71) Applicant: Mitsubishi Electric Corporation, Tokyo (JP)

(72) Inventors: Hiroki HIDAKA, Tokyo (JP); Satoshi MIYAHARA, Tokyo (JP)

(73) Assignee: Mitsubishi Electric Corporation, Tokyo (JP)

(21) Appl. No.: 19/047,559

(22) Filed: Feb. 6, 2025

(30) Foreign Application Priority Data
Mar. 11, 2024 (JP) 2024-037299

(51) Int. Cl. H01L 23/40; H01L 23/373; H01L 23/538; H01L 25/07

(52) U.S. Cl. CPC H01L 23/4006; H01L 23/3735; H01L 23/538; H01L 25/072

(57) ABSTRACT

A semiconductor apparatus according to the present disclosure includes: a semiconductor module including a heat dissipation plate; a heat sink including a mounting surface over which the semiconductor module is mounted; a heat dissipation member interposed between the heat dissipation plate and the heat sink and having flexibility; and a spacer. The semiconductor module and the heat sink are fastened together by a fastening member. The semiconductor module and the heat sink each include a fastening portion to which the fastening member is attached. The spacer is provided on the fastening portion of the semiconductor module or the fastening portion of the heat sink.

### CROSS REFERENCE TO RELATED APPLICATIONS

This nonprovisional application is based on Japanese Patent Application No. 2024-037299 filed on Mar. 11, 2024 with the Japan Patent Office, the entire contents of which are hereby incorporated by reference.

### BACKGROUND OF THE INVENTION

### Field of the Invention

The present disclosure relates to a semiconductor apparatus and a heat sink.

### Description of the Background Art

A related art technique is known, in which heat generated by a semiconductor module is dissipated by interposing a heat dissipation sheet or a heat dissipation member having flexibility, such as grease, between a heat sink and the semiconductor module. Also, another related art technique is known, in which a semiconductor module and a heat sink are fastened together by a fastening member, such as a screw.

Configurations of a semiconductor module and a heat sink of related art are described in Japanese Patent Laying-Open No. 2023-000129 for example. Japanese Patent Laying-Open No. 2023-000129 discloses a power semiconductor module provided with a semiconductor module including a base plate and a heat sink including a mounting surface on which the semiconductor module is mounted. Thermally conductive grease, which is a heat dissipation member, is interposed between the base plate provided on the lower surface of the semiconductor module and the heat sink, and the semiconductor module and the heat sink are fastened together by screws.

When, in the power semiconductor module described in Japanese Patent Laying-Open No. 2023-000129, the semiconductor module and the heat sink are fastened together by a screw, axial force is caused and the axial force concentrates on the fastening location. As a result of the concentration of the axial force on the fastening location, the fastening location in the semiconductor module sinks in relation to the central portion of the semiconductor module situated away from the fastening location. Consequently, in the heat dissipation member interposed between the base plate provided on the lower surface of the semiconductor module and the heat sink, a stress difference occurs between the vicinity of the fastening location and the central portion situated away from the fastening location. There has been a problem that a stress difference occurring in a heat dissipation member causes a crack in a member having relatively little flexibility, such as an insulation board included in a semiconductor module.

The present disclosure has been devised to solve the aforementioned problem and is aimed at providing a semiconductor apparatus that enables it to, when a semiconductor module and a heat sink are fastened together by a fastening member, inhibit occurrence of a stress difference in a heat dissipation member and inhibit a crack caused in an insulation board of the semiconductor module or the like due to stress.

### SUMMARY OF THE INVENTION

A semiconductor apparatus according to the present disclosure includes: a semiconductor module including a heat dissipation plate; a heat sink including a mounting surface over which the semiconductor module is mounted; and a heat dissipation member interposed between the heat dissipation plate and the heat sink and having flexibility. The semiconductor module and the heat sink are fastened together by a fastening member, the semiconductor module and the heat sink each include a fastening portion to which the fastening member is attached, and on the fastening portion, a spacer is provided between the semiconductor module and the heat sink.

The foregoing and other objects, features, aspects, and advantages of the present disclosure will become apparent from the following detailed description on the present invention, which will be understood in conjunction with the accompanying drawings.

### BRIEF DESCRIPTION OF THE DRAWINGS

FIG. 1 is a schematic cross-sectional view of a semiconductor apparatus according to a first embodiment.

FIG. 2 is a schematic top view of the semiconductor apparatus according to the first embodiment.

FIG. 3 is a schematic cross-sectional view of the semiconductor apparatus according to the first embodiment.

FIG. 4 is a schematic cross-sectional view of a semiconductor apparatus according to a second embodiment.

FIG. 5 is a schematic top view of the semiconductor apparatus according to the second embodiment.

FIG. 6 is a schematic cross-sectional view of the semiconductor apparatus according to a first variation of the second embodiment.

FIG. 7 is a schematic top view of the semiconductor apparatus according to the first variation of the second embodiment.

FIG. 8 is a schematic cross-sectional view of the semiconductor apparatus according to a second variation of the second embodiment.

FIG. 9 is a schematic top view of the semiconductor apparatus according to the second variation of the second embodiment.

FIG. 10 is a schematic cross-sectional view of the semiconductor apparatus according to a third variation of the second embodiment.

FIG. 11 is a schematic top view of the semiconductor apparatus according to the third variation of the second embodiment.

### DESCRIPTION OF THE PREFERRED EMBODIMENTS

### <Introduction>

In a direction parallel to a depth direction of a semiconductor apparatus, one side is expressed as “up” and the other side is expressed as “down”. In two main surfaces of a substrate, a layer, or another member, one surface is referred to as an upper surface and the other surface is referred to as a lower surface. The “up” and “down” direction is not limited to the gravitational direction or the direction at the time of mounting the semiconductor apparatus.

The drawings are illustrated schematically and the correlation between the size and the position in each of the images shown in different ones of the drawings is not necessarily indicated accurately but can be changed when needed. In the description below, similar components are given the same reference characters for illustration and also regarded as having similar names and functions. Thus, detailed descriptions of such components may not be repeated.

### First Embodiment

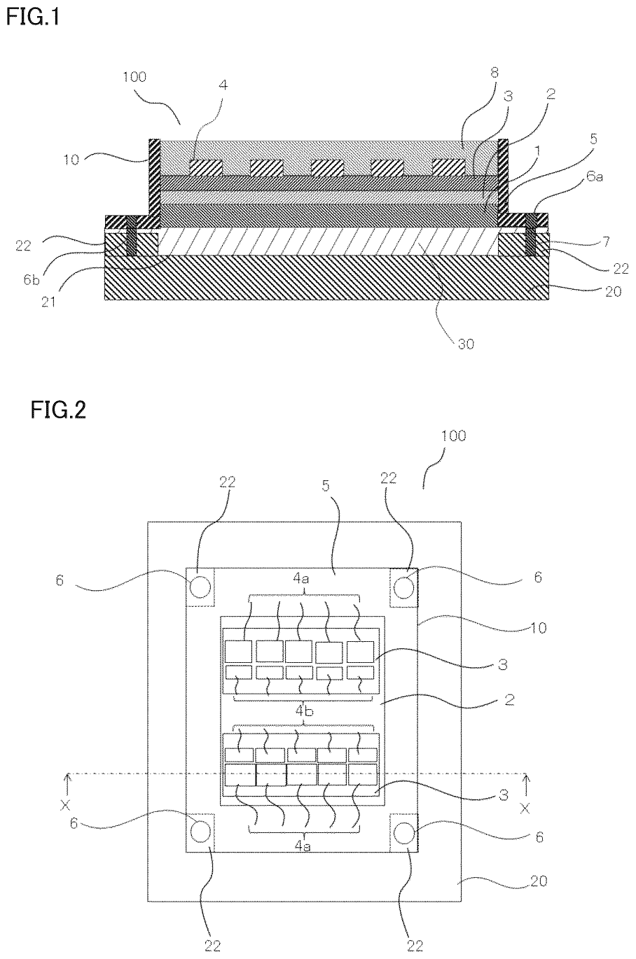

A first embodiment is described below with reference to the drawings. FIG. 1 is a schematic cross-sectional view of a semiconductor apparatus 100 according to the first embodiment. FIG. 2 is a schematic top view of semiconductor apparatus 100 according to the first embodiment. FIG. 1 illustrates a cross section along the dot-dashed line X-X in FIG. 2. In FIG. 1, for convenience of explanation, a fastening portion 6, a fastening member 7, and a spacer 22 are depicted in addition to the cross section along the dot-dashed line X-X in FIG. 2. Spacer 22 is indicated with the dotted line in FIG. 2.

A configuration of semiconductor apparatus 100 is described with reference to FIGS. 1 and 2. As illustrated in FIG. 1, semiconductor apparatus 100 includes a semiconductor module 10, a heat sink 20 including a mounting surface 21 over which semiconductor module 10 is mounted, and a heat dissipation member 30 interposed between a heat dissipation plate 1 of semiconductor module 10 and heat sink 20. First, a detailed configuration of semiconductor module 10 is described with reference to FIG. 1. Semiconductor module 10 includes heat dissipation plate 1 and an insulation board 2.

Heat dissipation plate 1 is composed of a material having electrical conductivity and thermal conductivity. For example, heat dissipation plate 1 is composed of a metal material, such as copper or aluminum.

Insulation board 2 is provided on the upper surface of heat dissipation plate 1. Insulation board 2 is mounted on the upper surface of heat dissipation plate 1 by soldering or the like for example. Insulation board 2 is composed of resin having electrical insulation properties and is composed of, for example, a ceramic.

As illustrated in FIG. 1, a metal pattern 3 may be provided on the upper surface of insulation board 2. Metal pattern 3 is mounted on the upper surface of insulation board 2 by soldering or the like for example. Metal pattern 3 is composed of metal having high electrical conductivity, such as copper.

As illustrated in FIG. 1, a semiconductor chip 4 is placed on metal pattern 3. Semiconductor chip 4 may be composed of Si or composed of SiC, GaN, or Ga₂O₃ as a wide band gap semiconductor. It is not particularly required to limit the device type of semiconductor chip 4, which may be a switching element 4a, such as an insulated gate bipolar transistor (IGBT) or a metal oxide semiconductor field effect transistor (MOSFET), or may be a freewheeling element 4b. For example, as illustrated in FIG. 2, semiconductor chip 4 may be constituted of a plurality of switching elements 4a and a plurality of freewheeling elements 4b. As illustrated in FIG. 2, the plurality of elements are arranged in the lateral direction and bonded via wires, which are not illustrated. The plurality of switching elements 4a and the plurality of freewheeling elements 4b are arranged so that each switching element 4a and a respective one of freewheeling elements 4b are disposed in the longitudinal direction. The plurality of freewheeling elements 4b are connected to the plurality of switching elements 4a in an anti-parallel manner and current flows equally therethrough.

Further, as illustrated in FIG. 1, semiconductor module 10 may include a case member 5 on its outer edge. Case member 5 is composed of resin having electrical insulation properties and bonded to heat dissipation plate 1. As illustrated in FIG. 2, case member 5 may be provided so as to surround the outer edge of, for example, insulation board 2 provided on heat dissipation plate 1.

As illustrated in FIG. 1, semiconductor module 10 is provided with fastening portion 6. Fastening portion 6 provided on semiconductor module 10 is referred to as a first fastening portion 6a and as illustrated in FIG. 1, in the present embodiment, first fastening portion 6a is provided in case member 5. Fastening member 7 for fastening semiconductor module 10 and heat sink 20 together is attached to fastening portion 6. Preferably, as illustrated in FIG. 2, first fastening portion 6a is provided in each of the four corners on the outer edge of semiconductor module 10.

Further, as illustrated in FIG. 1, semiconductor module 10 may be sealed with a sealing member 8. As illustrated in FIG. 1, in the present embodiment, sealing member 8 is provided on the inner side of case member 5. Sealing member 8 is composed of, for example, gel, resin, or the like having electrical insulation properties.

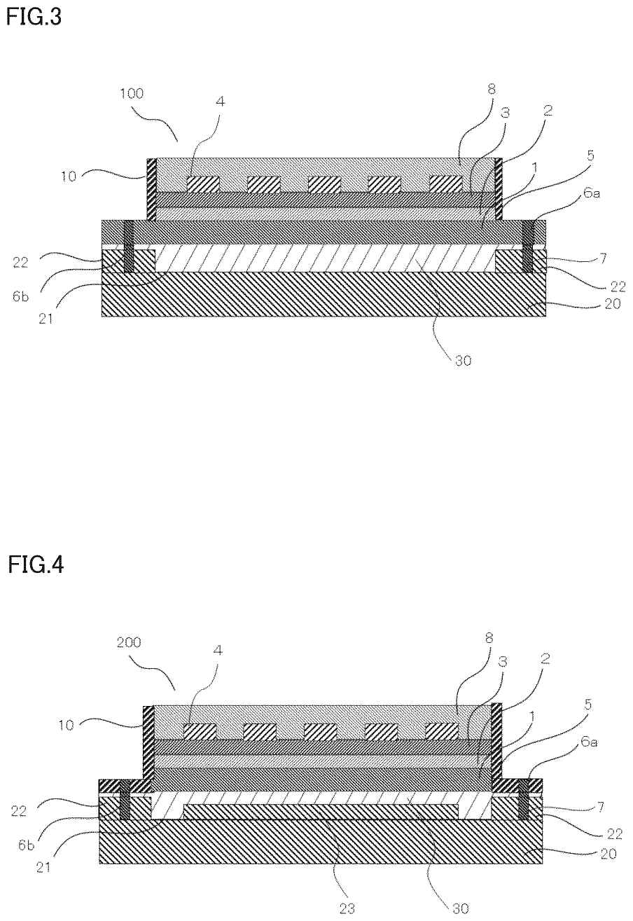

Semiconductor module 10 is configured as described above. As illustrated in FIG. 3, first fastening portion 6a on semiconductor module 10 may be provided in heat dissipation plate 1.

Referring to FIG. 1, heat dissipation member 30 is described next. As illustrated in FIG. 1, heat dissipation member 30 is provided so as to be interposed between heat dissipation plate 1 of semiconductor module 10 and heat sink 20. Heat dissipation member 30 is made of a material being high in thermal conductivity and having flexibility, such as thermal grease or a thermal sheet. The thickness of heat dissipation member 30 is approximately from 10 μm to 100 μm in the case of a thermal sheet, and is approximately from 50 μm to 100 μm in the case of thermal grease as the application amount. Heat dissipation member 30 is just required to be provided at least immediately under heat dissipation plate 1 and is not necessarily required to be provided immediately under case member 5.

Referring to FIGS. 1 and 2, heat sink 20 is described in detail next. As illustrated in FIG. 1, heat sink 20 includes mounting surface 21 over which semiconductor module 10 is mounted with interposition of heat dissipation member 30 having flexibility. Heat sink 20 is composed of metal having high thermal conductivity, such as aluminum. Further, heat sink 20 may include a fin formed on its lower surface side. Additionally, heat sink 20 includes fastening portion 6 to which fastening member 7 for fastening semiconductor module 10 and heat sink 20 together is attached. Fastening portion 6 provided on the heat sink 20 side is referred to as a second fastening portion 6b. Further, as illustrated in FIG. 1, on fastening portion 6, spacer 22 is provided between semiconductor module 10 and heat sink 20. As illustrated in FIG. 1, preferably, spacer 22 is provided on second fastening portion 6b and is provided in contact with mounting surface 21 of heat sink 20. Spacer 22 may be provided integrally with heat sink 20. As illustrated in FIG. 2, second fastening portion 6b and spacer 22 are preferably provided in each of the four corners on the outer edge of heat sink 20. Before the fastening by fastening member 7, the height of spacer 22 is smaller than or equal to the maximum thickness of heat dissipation member 30. As described above, the thickness of heat dissipation member 30 is approximately several tens of micrometers and accordingly, the height of spacer 22 is also approximately several tens of micrometers, which is smaller than or equal to the maximum thickness of heat dissipation member 30. Thus, heat dissipation member 30 can be brought into intimate contact with mounting surface 21 of heat sink 20 and semiconductor module 10 and heat dissipation performance can be secured. As illustrated in FIGS. 1 and 2, spacer 22 may be shaped like a cube or have any other shape. Preferably, as illustrated in FIGS. 1 and 2, the width of the spacer 22 is a width to spare in relation to the width of fastening member 7.

Although spacer 22 is provided on second fastening portion 6b on heat sink 20 in the description above, spacer 22 may be provided on first fastening portion 6a on semiconductor module 10. For example, spacer 22 may be provided in contact with the lower surface of case member 5, and may be provided integrally with case member 5. When thermal grease as heat dissipation member 30 is applied on semiconductor module 10, it is preferable for spacer 22 to be provided in contact with mounting surface 21 of heat sink 20 since the application of the thermal grease as heat dissipation member 30 onto the lower surface of heat dissipation plate 1 of semiconductor module 10 is facilitated.

As described above, semiconductor module 10 and heat sink 20 each include fastening portion 6 and identical fastening members 7 are inserted in the respective fastening portions 6, and semiconductor module 10 and heat sink 20 are fastened together by fastening member 7. Fastening portion 6 may be a screw hole and fastening member 7 may be a screw, a nut, or the like. As described above, fastening portions 6 are preferably provided in the four corners on the outer edge but are just required to be provided in at least two or more locations, and the locations and the number of fastening portions 6 may be selected as desired, depending on the size of the semiconductor apparatus, and the like. Fastening member 7 may be inserted from the lower surface side of heat sink 20.

Semiconductor apparatus 100 according to the present embodiment is configured as described above. The configuration where spacer 22 is provided on fastening portion 6 between semiconductor module 10 and heat sink 20 enables it to, when semiconductor module 10 and heat sink 20 are fastened together by fastening member 7, inhibit occurrence of a stress difference in heat dissipation member 30 and inhibit a crack caused in insulation board 2 of semiconductor module 10 or the like due to stress. The reasons therefor are described below.

In a conventional semiconductor apparatus, a mounting surface 21 of a heat sink 20 is flat and accordingly, a fastening portion 6 of a semiconductor module 10 sinks in relation to a central portion of semiconductor module 10 situated away from fastening portion 6. Thus, in a heat dissipation member 30, a stress difference occurs between the vicinity of fastening portion 6 and the central portion situated away from fastening portion 6. The stress difference occurring in heat dissipation member 30 causes a crack in a member having relatively little flexibility, such as an insulation board 2 included in semiconductor module 10. For example, when a first fastening portion 6a is provided in case member 5, a crack is caused in case member 5, and when first fastening portion 6a is provided in heat dissipation plate 1, a crack is caused in insulation board 2.

In semiconductor apparatus 100 according to the present embodiment, spacer 22 is provided on fastening portion 6 and it is thus enabled to inhibit, to an extent corresponding to the height of spacer 22, sinking of fastening portion 6 of semiconductor module 10 in relation to the central portion of semiconductor module 10 situated away from fastening portion 6. Accordingly, in heat dissipation member 30, a stress difference that occurs between the vicinity of fastening portion 6 and the central portion situated away from fastening portion 6 can be mitigated. As a result, a crack caused in a member having relatively little flexibility, such as insulation board 2 included in semiconductor module 10, can be inhibited and the reliability of the semiconductor apparatus can be increased.

A manufacturing method of semiconductor apparatus 100 according to the present embodiment is described next. Since the manufacturing method of semiconductor apparatus 100 according to the present embodiment is basically similar to a conventional manufacturing method of a semiconductor apparatus except a spacer formation step for heat sink 20, a formation step of semiconductor module 10 is not described below.

The manufacturing method of semiconductor apparatus 100 includes the spacer formation step, a heat dissipation member formation step, and a fastening step.

First, the spacer formation step is described. As an example of the formation method of spacer 22, a case where spacer 22 is provided integrally with heat sink 20 is described first. In heat sink 20 including mounting surface 21 that is flat, mounting surface 21 except second fastening portion 6b is shaved using, for example, a microgrinder or the like. Thus, spacer 22 can be formed on second fastening portion 6b.

When spacer 22 is provided as a member separate from heat sink 20, on heat sink 20 including mounting surface 21 that is flat, spacer 22 may be formed by being placed as the separate member on second fastening portion 6b in mounting surface 21. When spacer 22 is provided on first fastening portion 6a in semiconductor module 10, spacer 22 may be formed on first fastening portion 6a by shaping semiconductor module 10 by the above-described method.

Subsequently, the heat dissipation member formation step is described. Heat dissipation member 30 having flexibility is formed at least on the lower surface of heat dissipation plate 1 in semiconductor module 10. Thermal grease may be applied to the lower surface of heat dissipation plate 1 or a thermal sheet may be affixed to the lower surface of heat dissipation plate 1.

The fastening step is described next. First, semiconductor module 10 is mounted over heat sink 20 with heat dissipation member 30 interposed therebetween. After that, fastening member 7 is inserted into fastening portion 6 provided in semiconductor module 10 and heat sink 20. After that, heat sink 20 and semiconductor module 10 are fastened together by fastening member 7. Thus, semiconductor module 10, heat sink 20, and heat dissipation member 30 can be brought into intimate contact with each other.

Semiconductor apparatus 100 is manufactured by the foregoing steps. As described above, the manufacturing method of semiconductor apparatus 100 according to the present embodiment further includes the spacer formation step and spacer 22 is formed on fastening portion 6. The formation of spacer 22 enables it to, in the fastening step, to an extent corresponding to the height of spacer 22, inhibit sinking of fastening portion 6 of semiconductor module 10 in relation to the central portion of semiconductor module 10 situated away from fastening portion 6. Accordingly, in heat dissipation member 30, a stress difference that occurs between the vicinity of fastening portion 6 and the central portion situated away from fastening portion 6 can be mitigated. As a result, a crack caused in a member having relatively little flexibility, such as insulation board 2 included in semiconductor module 10, can be inhibited and the reliability of the semiconductor apparatus can be increased.

### Second Embodiment

Referring to FIGS. 4 and 5, a semiconductor apparatus 200 according to a second embodiment is described. FIG. 4 is a schematic cross-sectional view of semiconductor apparatus 200 according to the second embodiment. FIG. 5 is a schematic top view of semiconductor apparatus 200 according to the second embodiment. FIG. 4 illustrates a cross section along the dot-dashed line X-X in FIG. 5. In FIG. 4, for convenience of explanation, a fastening portion 6, a fastening member 7, and a spacer 22 are depicted in addition to the cross section along the dot-dashed line X-X in FIG. 5. Spacer 22 and a projecting portion 23 are indicated with the dotted lines in FIG. 5.

Semiconductor apparatus 200 according to the second embodiment further includes projecting portion 23 on a mounting surface 21 of a heat sink 20. As illustrated in FIGS. 4 and 5, projecting portion 23 is provided on a place of mounting surface 21 of heat sink 20, the place corresponding to a semiconductor chip 4. The height of projecting portion 23 is smaller than or equal to the height of spacer 22. A difference from the first embodiment is that projecting portion 23 is further provided on mounting surface 21 of heat sink 20. Projecting portion 23 is just required to be provided at least on a place of mounting surface 21 of heat sink 20, the place corresponding to semiconductor chip 4, or as illustrated in FIG. 5, projecting portion 23 may be provided only on a place of mounting surface 21 of heat sink 20, the place corresponding to semiconductor chip 4. The reasons therefor are described later. For example, when sets of semiconductor chips 4, each of which is constituted of a plurality of switching elements 4a and a plurality of freewheeling elements 4b, are separately provided in two locations as illustrated in FIG. 5, projecting portions 23 may also be separately provided only in two locations, each of which corresponds to a respective set of the plurality of switching elements 4a and the plurality of freewheeling elements 4b of semiconductor chips 4. As illustrated in FIGS. 4 and 5, projecting portion 23 is preferably shaped like a rectangular parallelepiped so as to agree with the shape of semiconductor chip 4 but may have any shape. Projecting portion 23 is preferably provided integrally with heat sink 20. Thus, thermal conductivity can be secured further in comparison with a case where projecting portion 23 is provided on heat sink 20 separately, and the heat dissipation performance can be increased.

Semiconductor apparatus 200 according to the second embodiment is configured as described above. Similar to the first embodiment, by employing the configuration where spacer 22 is provided on fastening portion 6 between semiconductor module 10 and heat sink 20, it is enabled to, when semiconductor module 10 and heat sink 20 are fastened together by fastening member 7, inhibit occurrence of a stress difference in a heat dissipation member 30 and inhibit a crack caused in an insulation board 2 of a semiconductor module 10 or the like due to stress.

Further, by employing the configuration where projecting portion 23 is provided on a place of mounting surface 21 of heat sink 20, the place corresponding to semiconductor chip 4, the heat dissipation performance of semiconductor module 10 can be enhanced. The reasons therefor are described below.

Immediately under semiconductor chip 4 mounted, which is a heat generation source of semiconductor module 10, the heat dissipation performance is needed the most. To enhance the heat dissipation performance, it is just required to raise the degree of contact between heat dissipation plate 1 of semiconductor module 10, and heat dissipation member 30 and heat sink 20 immediately under the semiconductor chip 4 mounted.

In semiconductor apparatus 200 according to the second embodiment, projecting portion 23 is provided on a place of mounting surface 21 of heat sink 20, the place corresponding to semiconductor chip 4. Thus, immediately under semiconductor chip 4, the distance between heat dissipation plate 1 and heat sink 20 is decreased, and with the decrease, the compressibility of the heat dissipation member is increased and the degree of contact can be raised accordingly. Owing to the raised degree of contact, the heat dissipation performance can be enhanced immediately under the mounted semiconductor chip 4, which is the heat generation source of semiconductor module 10.

The height of projecting portion 23 mentioned above is made smaller than or equal to the height of spacer 22. If the height of projecting portion 23 is larger than the height of spacer 22 when semiconductor module 10 is fastened to heat sink 20 with interposition of heat dissipation member 30, a phenomenon in which fastening portion 6 of semiconductor module 10 sinks in relation to the central portion of semiconductor module 10 situated away from fastening portion 6 occurs regardless of spacer 22 provided on fastening portion 6. As a result, in the heat dissipation member 30, a stress difference occurs between the location of projecting portion 23 provided on heat sink 20 and the location of spacer 22 provided on fastening portion 6. Accordingly, a crack is caused in case member 5 or insulation board 2, which has relatively little flexibility, and the reliability is decreased. Thus, by making the height of projecting portion 23 smaller than or equal to the height of spacer 22, occurrence of a stress difference between the location of projecting portion 23 and the location of spacer 22 in the heat dissipation member 30 can be inhibited. Consequently, the heat dissipation performance can be secured while occurrence of a fissure in case member 5 or a fissure in insulation board 2 can be inhibited with the reliability maintained.

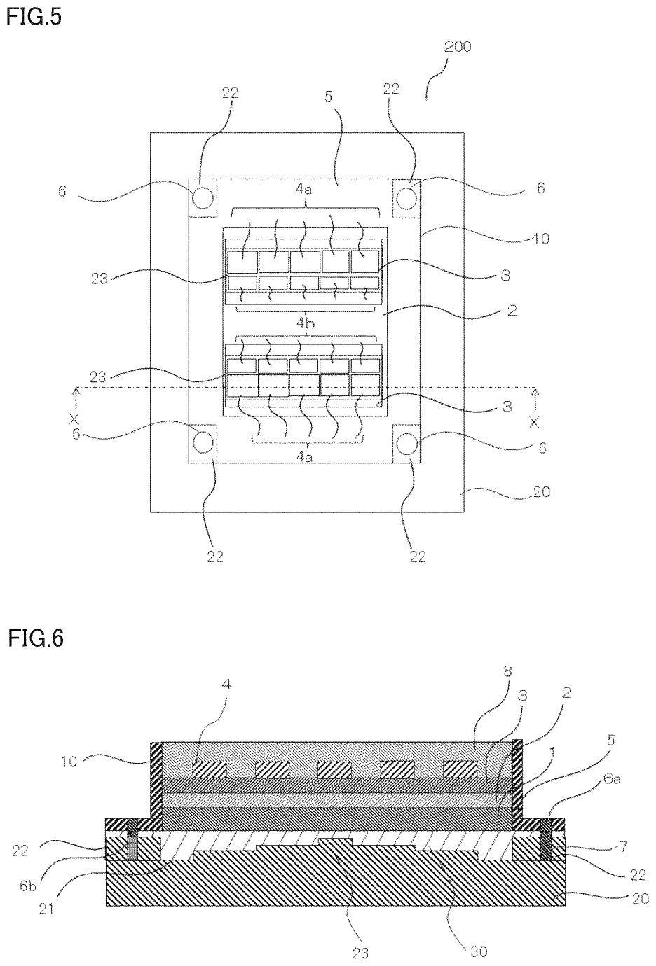

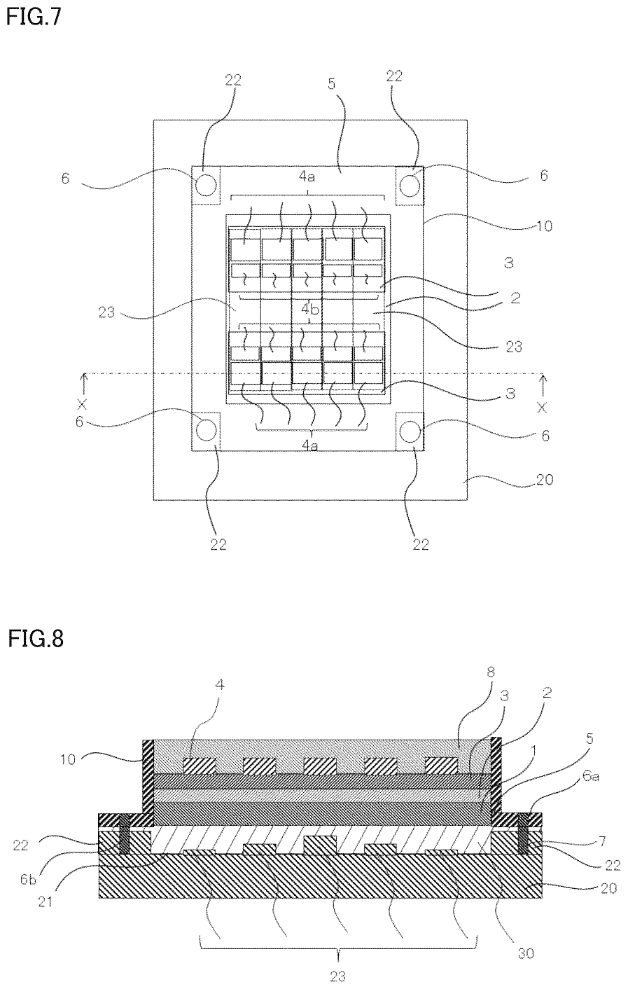

Referring to FIGS. 6 to 11, variations of the second embodiment are described next. First, the first variation is described with reference to FIGS. 6 and 7. FIG. 6 is a schematic cross-sectional view of the semiconductor apparatus according to the first variation. FIG. 7 is a schematic top view of the semiconductor apparatus according to the first variation. FIG. 6 illustrates a cross section along the dot-dashed line X-X in FIG. 7. In FIG. 6, for convenience of explanation, fastening portion 6, fastening member 7, and spacer 22 are depicted in addition to the cross section along the dot-dashed line X-X in FIG. 7. Spacer 22 and projecting portion 23 are indicated with the dotted lines in FIG. 7.

As illustrated in FIG. 6, projecting portion 23 may be provided so as to become higher toward the central portion of semiconductor module 10. The maximum height of projecting portion 23 is made smaller than the height of spacer 22. As illustrated in FIG. 6, projecting portion 23 may be provided in a stepped shape. As illustrated in FIG. 6, in projecting portion 23 provided in a stepped shape, the starting point of each level difference of the stairs may be caused to agree with a side surface on the outer edge side of corresponding one of semiconductor chips 4.

The plurality of semiconductor chips 4 placed in semiconductor module 10 each receive thermal interference due to heat generation of the other semiconductor chips 4 present around themselves. Thus, semiconductor chip 4 arranged closer to the central portion of semiconductor module 10 becomes higher in temperature and needs to have higher heat dissipation performance.

Since the semiconductor apparatus according to the first variation is provided so that projecting portion 23 becomes higher toward the central portion of semiconductor module 10, the degree of the contact between heat dissipation plate 1 of semiconductor module 10, and heat dissipation member 30 and heat sink 20 increases toward the central portion of semiconductor module 10. Thus, the heat dissipation performance can be enhanced selectively toward the module central portion where the temperature becomes higher.

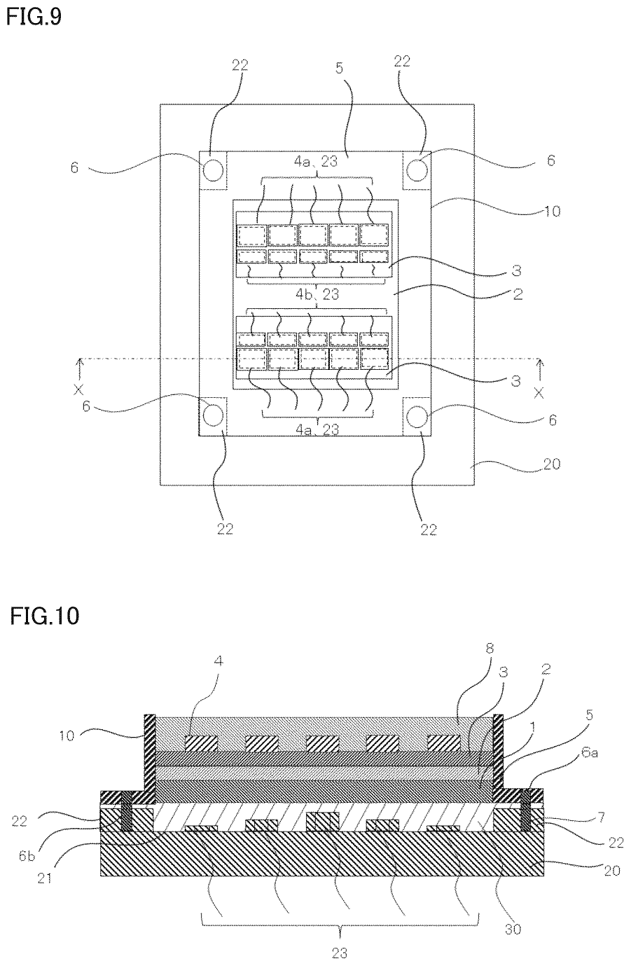

Referring to FIGS. 8 and 9, the second variation is described next. FIG. 8 is a schematic cross-sectional view of the semiconductor apparatus according to the second variation. FIG. 9 is a schematic top view of the semiconductor apparatus according to the second variation. FIG. 8 illustrates a cross section along the dot-dashed line X-X in FIG. 9. In FIG. 8, for convenience of explanation, fastening portion 6, fastening member 7, and spacer 22 are depicted in addition to the cross section along the dot-dashed line X-X in FIG. 9. Spacer 22 and projecting portion 23 are indicated with the dotted lines in FIG. 9.

As illustrated in FIG. 8, in the semiconductor apparatus according to the second variation, projecting portion 23 is provided so as to become higher toward the central portion of semiconductor module 10 similarly to the first variation. Further, as illustrated in FIGS. 8 and 9, in the semiconductor apparatus according to the second variation, projecting portion 23 is provided only on the places that respectively correspond to the plurality of semiconductor chips 4. The maximum height of projecting portion 23 is made smaller than the height of spacer 22.

Since the semiconductor apparatus according to the second variation is provided, similarly to the semiconductor apparatus according to the first variation, so that projecting portion 23 becomes higher toward the central portion of semiconductor module 10, the degree of the contact between heat dissipation plate 1 of semiconductor module 10, and heat dissipation member 30 and heat sink 20 increases toward the central portion of semiconductor module 10. Thus, the heat dissipation performance can be enhanced selectively toward the module central portion where the temperature becomes higher.

Further, in the semiconductor apparatus according to the second variation, projecting portion 23 is provided only on the places that respectively correspond to the plurality of semiconductor chips 4. Through the fastening, heat dissipation member 30 is compressed further in the location where projecting portion 23 is provided. Thus, when the range of projecting portion 23 provided on mounting surface 21 of heat sink 20 is wider, heat dissipation member 30 is compressed further and larger stress is caused in heat dissipation member 30. However, by providing projecting portion 23 only on the places that respectively correspond to the plurality of semiconductor chips 4, the stress caused in heat dissipation member 30 can be suppressed further in comparison with the first variation and the heat dissipation performance can also be maintained immediately under semiconductor chip 4.

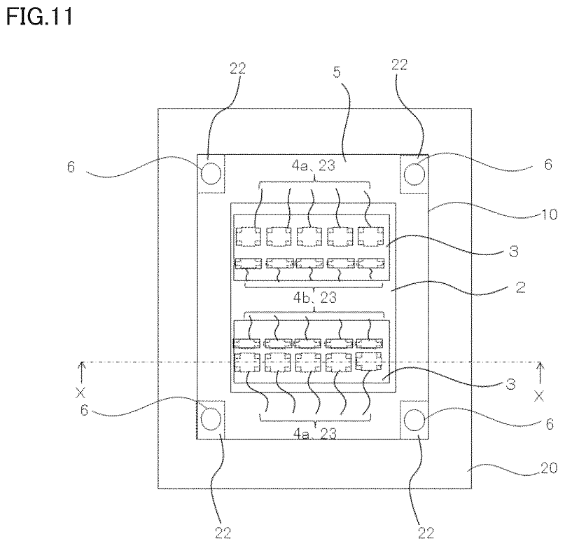

Referring to FIGS. 10 and 11, the third variation is described next. FIG. 10 is a schematic cross-sectional view of the semiconductor apparatus according to the third variation. FIG. 11 is a schematic top view of the semiconductor apparatus according to the third variation. FIG. 10 illustrates a cross section along the dot-dashed line X-X in FIG. 11. In FIG. 10, for convenience of explanation, fastening portion 6, fastening member 7, and spacer 22 are depicted in addition to the cross section along the dot-dashed line X-X in FIG. 11. Spacer 22 and projecting portion 23 are indicated with the dotted lines in FIG. 11.

As illustrated in FIGS. 10 and 11, in the semiconductor apparatus according to the third variation, similar to the semiconductor apparatus according to the second variation, projecting portion 23 is provided so as to become higher toward the central portion of semiconductor module 10 and is provided only on the places that respectively correspond to the plurality of semiconductor chips 4. Further, in the semiconductor apparatus according to the third variation, the upper surface of projecting portion 23 is made smaller in size than the bottom surface of semiconductor chip 4. The maximum height of projecting portion 23 is made smaller than the height of spacer 22.

Since the semiconductor apparatus according to the third variation is provided, similarly to the semiconductor apparatuses according to the first variation and the second variation, so that projecting portion 23 becomes higher toward the central portion of semiconductor module 10, the degree of the contact between heat dissipation plate 1 of semiconductor module 10, and heat dissipation member 30 and heat sink 20 increases toward the central portion of semiconductor module 10. Thus, the heat dissipation performance can be enhanced selectively toward the module central portion where the temperature becomes higher.

Further, in the semiconductor apparatus according to the third variation, similar to the semiconductor apparatus according to the second variation, projecting portion 23 is provided only on the places that respectively correspond to the plurality of semiconductor chips 4. Thus, the stress caused in heat dissipation member 30 can be suppressed and the heat dissipation performance can also be maintained immediately under semiconductor chip 4.

Moreover, in the semiconductor apparatus according to the third variation, the upper surface of projecting portion 23 is made smaller in size than the bottom surface of semiconductor chip 4. Thus, the stress caused in heat dissipation member 30 can be further suppressed. The size of the upper surface of projecting portion 23 is preferably made small so that its lower limit is 80% of the size of the bottom surface of semiconductor chip 4. When the upper surface of projecting portion 23 is made extremely smaller in size than the bottom surface of semiconductor chip 4, the contact area immediately under semiconductor chip 4 is reduced and the heat dissipation performance is decreased accordingly. Thus, by making the size of the upper surface of projecting portion 23 small so that its lower limit is 80% of the size of the bottom surface of semiconductor chip 4, it is enabled to further suppress the stress caused in heat dissipation member 30 while maintaining the heat dissipation performance. As illustrated in FIG. 11, the upper surface of projecting portion 23 may be shaped like a cross.

The configurations described above in the embodiments are presented as examples of the features of the present disclosure and can be combined with another known technique. Also, the embodiments and the variations can be combined with each other. Moreover, the configurations can be partly omitted or changed within the scope not departing from the gist of the present disclosure.

What is claimed is:

1. A semiconductor apparatus comprising:
a semiconductor module including a heat dissipation plate;
a heat sink including a mounting surface over which the semiconductor module is mounted;
a heat dissipation member interposed between the heat dissipation plate and the heat sink and having flexibility; and
a spacer, wherein
the semiconductor module and the heat sink are fastened together by a fastening member,
the semiconductor module and the heat sink each include a fastening portion to which the fastening member is attached, and
the spacer is provided on the fastening portion of the semiconductor module or the fastening portion of the heat sink.

2. The semiconductor apparatus according to claim 1, wherein a height of the spacer is smaller than or equal to a maximum thickness of the heat dissipation member before fastening.

3. The semiconductor apparatus according to claim 1, wherein the spacer is provided in contact with the mounting surface of the heat sink.

4. The semiconductor apparatus according to claim 3, wherein the spacer is provided integrally with the heat sink.

5. The semiconductor apparatus according to claim 1, wherein
the semiconductor module includes a case member on an outer edge of the semiconductor module, and
the fastening portion of the semiconductor module is provided in the case member.

6. The semiconductor apparatus according to claim 1, wherein the fastening portion of the semiconductor module is provided in the heat dissipation plate.

7. The semiconductor apparatus according to claim 1, wherein the fastening portion is provided in each of at least two or more locations.

8. The semiconductor apparatus according to claim 1, wherein
the semiconductor module includes a semiconductor chip,
the heat sink includes a projecting portion provided on a place of the mounting surface, the place corresponding to the semiconductor chip, and
a height of the projecting portion is smaller than or equal to a height of the spacer.

9. The semiconductor apparatus according to claim 8, wherein the projecting portion is provided so as to become higher toward a central portion of the semiconductor module.

10. The semiconductor apparatus according to claim 9, wherein the projecting portion is provided in a stepped shape.

11. The semiconductor apparatus according to claim 8, wherein the projecting portion is provided only on the place corresponding to the semiconductor chip.

12. The semiconductor apparatus according to claim 11, wherein an upper surface of the projecting portion is smaller in size than a bottom surface of the semiconductor chip.

13. A heat sink comprising:
a mounting surface over which a semiconductor module is to be mounted with interposition of a heat dissipation member having flexibility;
a fastening portion to which a fastening member for fastening the semiconductor module and the heat sink together is to be attached, the fastening portion being provided on the mounting surface; and
a spacer provided on the fastening portion.

14. The heat sink according to claim 13, wherein a height of the spacer is smaller than or equal to a maximum thickness of the heat dissipation member before fastening.

15. The heat sink according to claim 13, wherein the fastening portion is provided in each of at least two or more locations.

16. The heat sink according to claim 13, wherein
the semiconductor module includes a semiconductor chip, and
the heat sink further includes a projecting portion provided on a place of the mounting surface, the place corresponding to the semiconductor chip, a height of the projecting portion being smaller than or equal to a height of the spacer.

17. The heat sink according to claim 16, wherein the projecting portion is provided so as to become higher toward a central portion of the semiconductor module.

18. The heat sink according to claim 17, wherein the projecting portion is provided in a stepped shape.

19. The heat sink according to claim 16, wherein the projecting portion is provided only on the place corresponding to the semiconductor chip.

20. The heat sink according to claim 19, wherein an upper surface of the projecting portion is smaller in size than a bottom surface of the semiconductor chip.
